(19) United States
(12) Patent Application Publication
(10) Pub. No.: US 2026/0351895 A1
(43) Pub. Date: Nov. 5, 2026

(54) INTERFACE MODULE AND HEATSINK SYSTEM

(71) Applicant: NOKIA SOLUTIONS AND NETWORKS OY, Espoo (FI)

(72) Inventors: Sheng Xu, Zhejiang (CN); Hai Wu, Zhejiang (CN); Xiongxiong Hu, Zhejiang (CN)

(21) Appl. No.: 19/478,475

(22) PCT Filed: Apr. 28, 2023
(86) PCT No.: PCT/CN2023/091763

§ 371 Date: Oct. 24, 2025

(51) Int. Cl. H01R 13/533; H05K 7/20

(52) U.S. Cl. CPC H01R 13/533; H05K 7/20472

(57) ABSTRACT

Example embodiments of the present disclosure relate to an interface module and a heatsink system. The interface module includes a frame enclosing an internal channel for receiving at least a heating portion of a heating apparatus in an inserting direction; at least one heat spreader provided adjacent to an inner wall of the internal channel and configured to contact the heating portion when the heating apparatus is within the internal channel; and at least one pair of holders attached to the frame and connected to the heat spreader, the holder being configured to restrict a movement of the heat spreader along one or more directions perpendicular to the inserting direction. According to the example embodiment of the present disclosure, the heat spreader can freely float relative to the frame of the interface module to allow the heat spreader to adjust its position flexibly.

### FIELD

Example embodiments of the present disclosure generally relate to the field of telecommunication, and in particular, to an interface module and a corresponding heatsink system to dissipate the heat.

### BACKGROUND

As the development of telecommunication technology, the transmission speed of SFP (small form-factor pluggable) transceiver is becoming increasingly high, from 5 Gbps, 10 Gbps to 25 Gpbs, 40 Gbps, and even up to 100 Gpbs. SFP transceiver is widely used in telecommunication field, and it can be connected to a SFP connector on PCB which is inside of a variety of units. The transceiver in operation will generate heat, which should be dissipated quickly to prevent the transceiver from failing to meet the temperature specification.

A number of approaches have been proposed to dissipate the heat generated by the SFP transceiver. One approach is to add a sheet metal spring clip and thermal pad on one side of a SFP heatsink, to ensure heat to be dissipated via SFP heatsink. However, the SFP transceiver only contact with SFP heatsink on one side via the spring clip and thermal pad causing the other side of the transceiver not to contact the heatsink. As a result, the thermal resistance between SFP transceiver and SFP heatsink is big and unstable. The heat dissipation performance is undesirable.

Another approach is to add thermal pads on both sides of the sheet metal cage before assembling the cage to the SFP heatsink, and then to fix the cage to SFP heatsink with screws. However, the screws will limit floating of the cage and may impact the contact status in actual application due to tolerance accumulation. Worse still, there will be also gap between SFP transceiver and SFP cage. Therefore, the heat conduction route is discontinuous, which increases thermal conduction resistance.

U.S. Pat. No. 10,389,397 B2 proposes an approach with one spring contact added between a thermal interface material and a SFP transceiver. The spring contact is fixed on SFP cage and is wrapped with graphite sheets. In this approach, even though a stable heat dissipation performance may be achieved, its manufacture process may be difficult since it's structurally hard to wrap the graphite sheet in this approach. More critically, this approach cannot be applied in some concrete cases.

Therefore, how to resolve heat dissipation issue for high thermal power SFP transceiver remains a challenge to the designers.

### SUMMARY

In general, example embodiments of the present disclosure propose a solution for efficiently improving the heat dissipating performance of the interface module.

In a first aspect, there is provided an interface module. The interface module comprising: a frame enclosing an internal channel for receiving at least a heating portion of a heating apparatus in an inserting direction; at least one heat spreader provided adjacent to an inner wall of the internal channel and configured to contact the heating portion when the heating apparatus is within the internal channel; and at least one pair of holders attached to the frame and connected to the heat spreader, the holder being configured to restrict a movement of the heat spreader along one or more directions perpendicular to the inserting direction.

In some example embodiments, the frame comprises a first end, and wherein the frame further comprises a first stop provided adjacent to the first end and configured to restrict a movement of the frame along the inserting direction.

In some example embodiments, the frame further comprises a second end opposite to the first end, and wherein the frame further comprises a second stop provided adjacent to the second end and configured to restrict the movement of the frame opposite to the inserting direction.

In some example embodiments, at least one of the first stop and the second stop is formed as a part of the holder.

In some example embodiments, the at least one heat spreader comprises at least one pair of heat spreader segments which are provided in opposite directions about a central line of the internal channel.

In some example embodiments, a cross section of the internal channel is of a shape selected from any of the following: rectangle, square, circle, and ellipse.

In some example embodiments, a cross section of the internal channel is of a rectangle, and the frame comprises: a first face and a second face opposite to each other; a third face adjoining the first face and the second face; and a fourth face adjoining the first face and the second face, the fourth face being opposite to the third face.

In some example embodiments, the heat spreader further comprises: a first heat spreader provided at the first face; and a second heat spreader provided at the second face.

In some example embodiments, each of the at least one heat spreader comprises: a flat surface parallel to the inserting direction and configured to contact the heating portion when the heating apparatus is being inserted; and at least one tab adjacent to the flat surface and couple to the holder, so as to restrict the movement of the heat spreader.

In some example embodiments, the heating apparatus is a small form-factor pluggable transceiver.

In a second aspect, there is a heatsink system. The heatsink system comprises an interface module of the first aspect; a heatsink coupled to the interface module, wherein a portion of the heatsink is provided outside at least a portion of the interface module; and at least one resilient heat conducting material provided between the interface module and the portion of the heatsink, wherein the heat generated by the heating apparatus is conducted to the resilient heat conducting material via the heat spreader of the interface module, and then dissipated by the heatsink.

In some example embodiments, the heat spreader is configured to move away from a center of the frame of the interface module when the heating apparatus is inserted into the internal channel of the interface module, so as to compress the resilient heat conducting material along a compressing direction perpendicular to the inserting direction.

In some example embodiments, a cross section of the internal channel of the interface module is of a rectangle, and the frame comprises: a first face and a second face opposite to each other; a third face adjoining the first face and the second face; and a fourth face adjoining the first face and the second face, the fourth face being opposite to the third face, and wherein the heat spreader of the interface module further comprising: a first heat spreader provided at the first face; and a second heat spreader provided at the second face, wherein the distance between the first heat spreader and the second heat spreader when the heating apparatus not being inserted into the internal channel is smaller than the distance between the first face and the second face.

In some example embodiments, the distance between the first heat spreader and the second heat spreader when the heating apparatus being inserted into the internal channel is equal to a first dimension of the heating apparatus.

In some example embodiments, the heat spreader and the resilient heat conducting material are integrally formed as one piece.

In some example embodiments, the resilient heat conducting material is made of a thermal interface material selected from any of the following: graphite over foam, gel, grease, pad and phase change material.

In some example embodiments, the frame of the interface module further comprises a first stop and a second stop, and wherein the heatsink comprises: a first position limit configured to couple to the first stop to restrict the movement of the frame along the inserting direction; and a second position limit configured to couple to the second stop to restrict the movement of the frame opposite to the inserting direction.

In some example embodiments, the first position limit and the second position limit are recesses or protrusions provided on the heatsink, and the first stop and the second stop are protrusions or recesses provided at the frame.

### BRIEF DESCRIPTION OF THE DRAWINGS

Through the following detailed description with reference to the accompanying drawings, the above and other objectives, features and advantages of the example embodiments disclosed herein will become more comprehensible. In the drawings, several example embodiments disclosed herein will be illustrated in an exemplary and in a non-limiting manner, wherein:

FIG. 1 illustrates an exemplary perspective view of a heatsink system in accordance with example embodiments of the present disclosure;

FIG. 2 illustrates an exemplary front view of a heatsink system in accordance with an example embodiment of the present disclosure, with a transceiver coupled to an interface module of the heatsink system;

FIG. 3 illustrates an exemplary perspective view of a heatsink system in accordance with example embodiments of the present disclosure, wherein an interface module and a resilient heat conducting material of the heatsink system is shown in an exploded view, with the interface module not being coupled to the heatsink;

FIG. 4 illustrates an exemplary perspective view of an interface module in accordance with an example embodiment of the present disclosure;

FIG. 5 illustrates an exemplary perspective view of an interface module in accordance with another example embodiment of the present disclosure;

FIG. 6 illustrates an exemplary sectional view of a heatsink system in accordance with example embodiments of the present disclosure with a transceiver not being coupled to the heatsink system;

FIG. 7 illustrates an exemplary sectional view of a heatsink system in accordance with example embodiments of the present disclosure with a transceiver being coupled to the heatsink system;

FIG. 8 illustrates an exemplary perspective view of a heatsink system in accordance with other example embodiments of the present disclosure;

FIG. 9 illustrates an exemplary perspective view of an interface module in accordance with other example embodiments of the present disclosure;

FIG. 10 illustrates an exemplary sectional view of a heatsink system in accordance with other example embodiments of the present disclosure with a transceiver not being coupled to the heatsink system; and

FIG. 11 illustrates an exemplary sectional view of a heatsink system in accordance with other example embodiments of the present disclosure with a transceiver being coupled to the heatsink system.

Throughout the drawings, the same or similar reference numerals represent the same or similar element.

### DETAILED DESCRIPTION

Principles of the present disclosure will now be described with reference to some example embodiments. It is to be understood that these embodiments are described only for the purpose of illustration and to help those skilled in the art to understand and implement the present disclosure, without suggesting any limitation as to the scope of the disclosure. The disclosure described herein can be implemented in various manners other than the ones described below.

In the following description and claims, unless defined otherwise, all technical and scientific terms used herein have the same meaning as commonly understood by one of ordinary skill in the art to which this disclosure belongs.

References in the present disclosure to “one embodiment,” “an embodiment,” “an example embodiment,” and the like indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to apply such feature, structure, or characteristic in connection with other embodiments whether or not explicitly described.

It should be understood that although the terms “first” and “second” etc. may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the listed terms.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components etc., but do not preclude the presence or addition of one or more other features, elements, components and/or combinations thereof. It should be understood that, the terms “parallel” and “perpendicular” as used herein may refer to strictly parallel and strictly perpendicular, respectively, and may also refer to substantially parallel and substantially perpendicular within a margin of error due to the manufacturing process (e.g. within ±0.5° or ±1°). It will be appreciated by those skilled in the art that such errors do not result in significant degradation of performance and therefore would not depart from the scope of present disclosure.

At least to address the above problems existed in the related approaches; the present disclosure proposes a self-adaptive heat dissipation solution which eliminates the gap between an interface module and a heatsink by using a self-adaptive structure to achieve higher heat dissipating rate. Moreover, with the help of the stops provided on the interface module and the associated position limit provided on the heatsink, the interface module may be fixed to the heatsink without screws and the interface module can self-adjust its posture with relative to the heatsink.

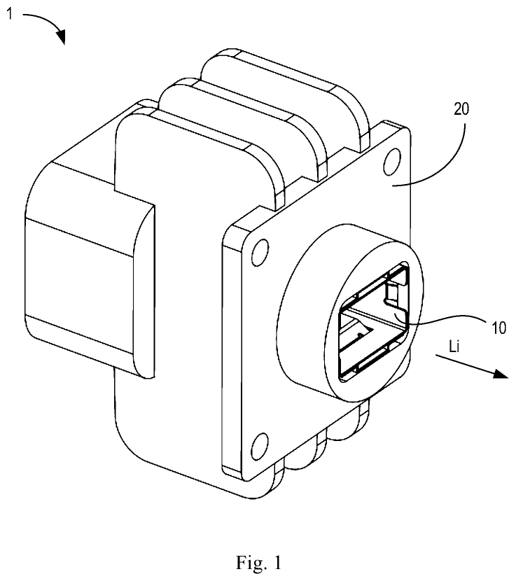

Example embodiments will be described in more detail hereinafter in accordance with FIGS. 1-11.

FIG. 1 illustrates an exemplary perspective view of a heatsink system 1 in accordance with example embodiments of the present disclosure. As shown in FIG. 1, the heatsink system 1 generally includes a heatsink 20 and an interface module 10 coupled to the heatsink 20. The heatsink 20 includes a hole to accommodate the interface module 10. As shown, the hole used for receiving the interface module 10 is in the center portion of the heatsink. However, it is to be understood that the position and the shape of the hole are not limited to the illustrated embodiment and they can be adjusted according to the actual need. When being used, the interface module 10 is inserted into the hole of the heatsink 20 to receive a portion of a heating apparatus.

In the example embodiments described herein, the heating apparatus may be implemented as a transceiver. In further example embodiments, the transceiver may be a small form-factor pluggable transceiver. It can be understood that these are merely illustrative, rather than restrictive. In other example embodiments, the heating apparatus may be all kinds of small form-factor pluggable transceiver or even other components other than a transceiver, as long as the heating apparatus needs to be cooled down by means of the heatsink 20.

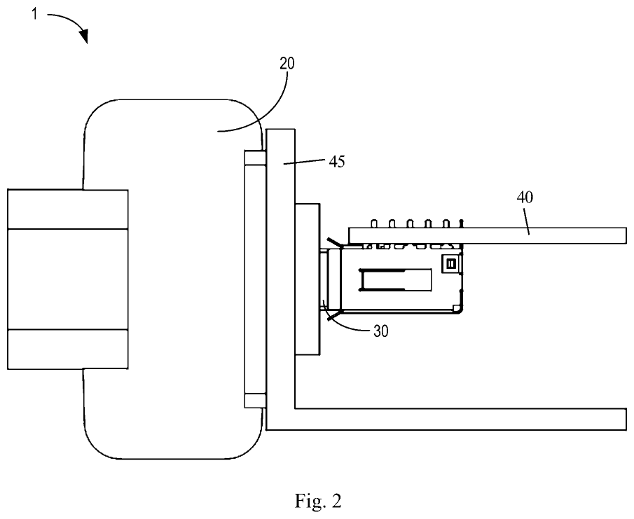

FIG. 2 illustrates an exemplary front view of a heatsink system 1 in accordance with an example embodiment of the present disclosure, with a transceiver 30 coupled to the heatsink system 1. An external information can be transmitted to the PCB 40 via the transceiver 30 and the transceiver 30 may generate heat during operation. The heat should be dissipated by the heatsink 20. The heatsink 20 is coupled to an interface module 10 and is used to dissipate the heat generated by the transceiver 30 to an ambient environment via one or more cooling fins. The details of the interface module 10 will be described hereinafter with reference to other figures.

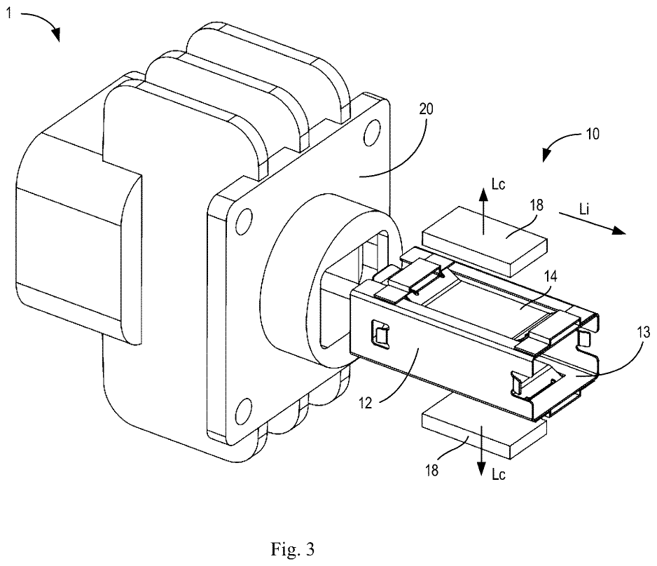

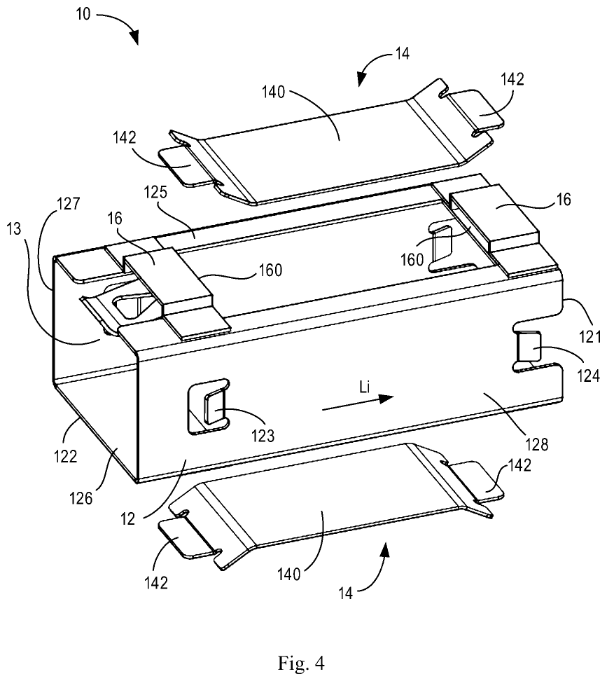

FIG. 3 illustrates an exemplary perspective view of a heatsink system 1 in accordance with example embodiments of the present disclosure, wherein the interface module 10 and a resilient heat conducting material 18 of the heatsink system 1 is shown in an exploded view, with the interface module 10 not being coupled to the heatsink 20. FIG. 4 illustrates an exemplary perspective view of the interface module 10 in accordance with example embodiments of the present disclosure.

As shown in FIG. 4, the interface module 10 includes a frame 12, and the frame 12 encloses an internal channel 13 for receiving a heating portion of the transceiver 30. The transceiver 30 may be inserted into the internal channel 13 of the frame 12 in an inserting direction Li. The inserting direction Li is the direction along with the transceiver 30 is inserted. When the transceiver 30 is in operation, the heating portion will generate heat and the heat should be dissipated in order to protect the surrounding components from being damaged. The heating portion may be any portion of the transceiver 30 and its position or designed function is not limited to the present disclosure. The heat may be produced by the heating portion itself, or may be conducted internally by the transceiver 30. In the shown embodiment, the sectional area of the frame 12 is rectangle. However, this is merely illustrative, without suggesting any limitations as to the scope of the subject matter described here. The sectional area of the frame 12 may also be of any suitable shape, including but not limited to square, circle, and ellipse, etc.

With still reference to FIG. 4, the interface module 10 further includes at least one heat spreader 14 and at least one pair of holders 16 for use with the heat spreader 14. The heat spreader 14 is provided adjacent to an inner wall of the internal channel 13 and configured to contact the heating portion when the transceiver 30 is inserted within the internal channel 13. The holder 16 is attached to the frame 12 and connected to the heat spreader 14. The holder 16 is used to restrict a movement of the heat spreader 14 along one or more directions perpendicular to the inserting direction Li.

As shown in FIG. 4, the pair of holders 16 are located at both sides of the heat spreader 14.

It should be noted that, the holders 16 are not used to disable the movement of the heat spreader 14. Instead, the holders 16 are provided to guide the movement of the heat spreader 14, which means the heat spreader 14 can still be driven to move relative to the holders 16. This will be described in more detail hereinafter.

With reference back to FIG. 4, as can be seen, the frame 12 generally has four faces. Among those faces, a first face 125 and a second face 126 are opposite to each other, a third face 127 adjoins the first face 125 and the second face 126; and a fourth face 128 adjoining the first face 125 and the second face 126, and the fourth face 128 is provided to be opposite to the third face 127. These four faces together constitute the rectangle cross sectional of the internal channel 13 of the frame 12.

As can be seen from FIG. 4, two heat spreaders 14 are shown, wherein an upper one is shown to be provided at the first face 125 and a lower one is shown to be provided at the second face 126. For the upper heat spreader 14, two related holders 16 are provided nearby at opposite sides. In the illustrated embodiments, the two holders 16 are secured to the frame 12. As shown, there is a slot 160 between the each holder 16 and the frame 12.

With still reference to FIG. 4, each of the heat spreader 14 generally includes a flat surface 140 and at least one tab 142. The flat surface 140 may be the main body of the heat spreader 14 and the each tab 142 protrudes from the flat surface 140. In the illustrated embodiment, two tabs 142 are provided in each heat spreader 14 and they are provided at opposite sides of the flat surface 140. The flat surface 140 is parallel to the inserting direction Li and may be provided to contact the heating portion when the transceiver 30 is inserted into the internal channel 13 of the frame 12. It is to be understood that the heat spreader 14 may include a surface and a tab with other shapes. For example, if the cross section of the internal channel 13 of the frame 12 is circle or ellipse, the surface and the tab may be of a curved shape to match the internal channel 13.

When being used, each tab 142 may be placed into the respective slot 160 between the holder 16 and the frame 12. The heat spreader 14 and the holder 16 are dimensioned such that the movement of the heat spreader 14 along the inserting direction Li is inhibited by the holder 16. Also, the tab 142 of the heat spreader 14 and the slot 160 are dimensioned such that the tab 142 may move along the directions perpendicular to the inserting direction Li within the slot 160. In this way, the heat spreader 14 is allowed to move freely relative to the holder 16. Since the holder 16 is fixedly mounted to the frame 12, the heat spreader 14 is allowed to move freely relative to the frame 12.

According to the example embodiment of the present disclosure, the heat spreader 14 can freely “float” relative to the frame 12 of the interface module 10. When the transceiver 30 is inserted into the internal channel 13 of the frame 12, the heat spreader 14 can adapt its position accordingly. By virtual of this self-adaptive function, the gap in the heat dissipating route can be eliminated. Therefore, the heat dissipation performance can be kept good and stable.

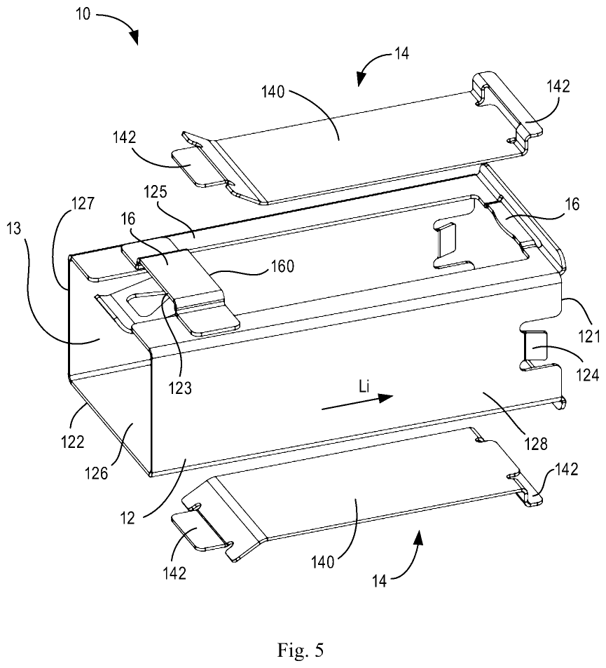

FIG. 5 illustrates an exemplary perspective view of an interface module in accordance with another example embodiment of the present disclosure. FIG. 5 differs from FIG. 4 in the specific configuration of one holder 16. In the embodiments as shown in FIG. 5, one holder (left one) of the pair of holder 16 is securely mounted to the frame 12 and the other holder (right one) is formed as an integral part of the frame 12. There is also a slot 16 between the left holder 16 and the frame 12.

With still reference to FIG. 5, similarly to the embodiments described above, the tab 142 of the heat spreader 14 and the slot 160 are dimensioned such that the tab 142 may move along the directions perpendicular to the inserting direction Li within the slot 160. In this way, the heat spreader 14 is allowed to move freely relative to the holder 16, with only the movement along the inserting direction Li is restricted.

With reference back to FIG. 4, the frame 12 may further include one or more first stops 124. The first stops 124 are used for restricting the movement of the frame 12 along the inserting direction Li. The position and the shape of first stops 124 are designed to match a position limit provided at the inner surface of the heatsink 20. In some example embodiments, the mating position limit may be a recess, with number, position and shape corresponding to that of the first stop 124. As the frame 12 is being inserted along a direction parallel to the inserting direction Li relative to the heatsink 20, the first stops 124 of the frame 12 will finally touch the mating position limit of the heatsink 20 and partially “lock” the frame 12 to the heatsink 20. As a result, the movement of the frame 12 along the inserting direction Li will be inhibited. However, the frame 12 can still move along other directions than the inserting direction. For example, the frame 12 is allowed to move relative to the heatsink 20 in an up and down direction illustrated in FIG. 4.

As can be seen from FIG. 4, the frame 12 has a first end 121 and a second end 122 opposite to the first end 121. The first stop 124 may be provided adjacent to the first end 121. In the illustrated embodiment, the first stop 124 is formed as an integral part of the frame 12. The frame 12 may further include a second stop 123 adjacent to the second end 122 and the second stop 123 is used to restrict the movement of the frame 12 opposite to the inserting direction Li. Like the first stop 124, the second stop 123 is designed to match a mating position limit provided at the inner surface of the heatsink 20. With the first stop 124 and the second stop 123, the relative movement between the frame 12 and the heatsink 20 along the inserting direction Li can be inhibited.

In some example embodiments, the first stop 124 and/or the second stop 123 may be formed as a part of the frame 12 and/or as a part of the holder 16. For example, as illustrated in FIG. 4, both the first stop 124 and the second stop 123 are protrusions provided on the frame 12. Moreover, in the example embodiments as shown in FIG. 5, the first stop 124 is a protrusion provided on the frame and the second stop 123 is formed as an integral part of the holder 16. In a specific embodiment, the second stop 123 may be the side face of the holder 16. In other example embodiments, the first stop 124 may also be an integral part of the holder 16. In other embodiments, both the first stop 124 and the second stop 123 can be integral part of the respective holder 16.

Even though two heat spreaders 14 are shown in FIGS. 4-5, it is to be understood that the number of the heat spreaders 14 are merely example without suggesting any limitation as to the scope of the present disclosure. In other example embodiments, the interface module 10 may include one heat spreader or more than two heat spreaders, depending on the actual need of the users. For example, in other example embodiments, the interface module 10 may include two more heat spreaders 14 at the third face 127 and the fourth face 128.

With the first stop 124 and/or the second stop 123, no screws are required when assembling the frame 12 to the heatsink 20. In the existing solution using screws, due to the tolerance accumulation, the screws will limit the floating of the frame and will eventually impact the contact status in actual application. According to the example embodiments, the limitation brought about by the screws can be avoided.

In further example embodiments, if the cross section of the internal channel 13 of the frame 12 is a circle, the heat spreaders 14 may be distributed evenly about the centroid of the circle. For example, if three heat spreaders 14 are included around the frame 12, they may be located with 120 degrees apart from each other. If four heat spreaders 14 are included around the frame 12, they may be located with 90 degrees apart from each other.

In some example embodiments, the holder 16 may be provided in pairs. It is to be understood that if the cross section of the internal channel 13 is circle or ellipse, the pair of the holder 16 may be formed in opposite directions about a central line of the internal channel 13. The heat spreader 14 is used with the holder 16, and therefore, if the cross section of the internal channel 13 is circle or ellipse, the heat spreader 14 may, for example, include at least one pair of heat spreader segments formed in opposite directions about a central line of the internal channel 13.

In some example embodiments, the heat spreader 14 may be a sheet metal part. In further example embodiments, the heat spreader 14 may be made of stainless steel or copper etc. It is to be understood that other material for the heat spreader 14 are also possible in terms of cost and performance consideration, for example, the heat spreader 14 may be made of flatten vapor chamber (VC) or other kind of heat pipe.

With reference back to FIG. 3, a portion of the heatsink 20 is provided outside the interface module 10; and the resilient heat conducting material 18 may be provided between the interface module 10 and the portion of the heatsink 20, such that the heat generated via the heating portion can be conducted to the resilient heat conducting material 18 via the heat spreader 14 of the interface module 10, and then dissipated by the heatsink 20.

In this way, since the movement of the heat spreader 14 is only restricted along the inserting direction Li and the heat spreader is allowed to move relative to the frame 12 in various directions (for example, a direction perpendicular to the inserting direction Li), when the transceiver 30 is inserted into the internal channel 13 of the frame 12, the heat spreader 14 may move away from a center of the frame 12 of the interface module 10 along a compressing direction Lc, so as to firmly compress the resilient heat conducting material 18 along the compressing direction Lc. The compressing direction Lc is a direction along which the resilient heat conducting material 18 is compressed. In this way, there will not be any gap between the transceiver 30 and the heat spreader 14, the thermal resistance from the transceiver 30 to heatsink 20 can be reduced significantly, thus greatly improving the heat dissipation performance.

According to the example embodiments, the resilient heat conducting material 18 can be flexibly assembled to the heatsink 20 via the interface module 10.

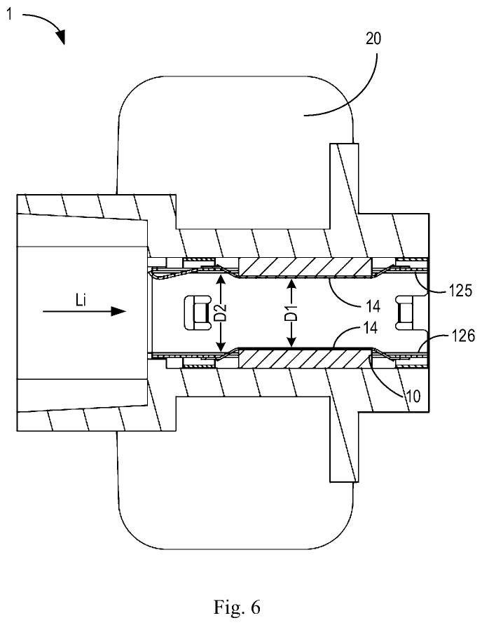

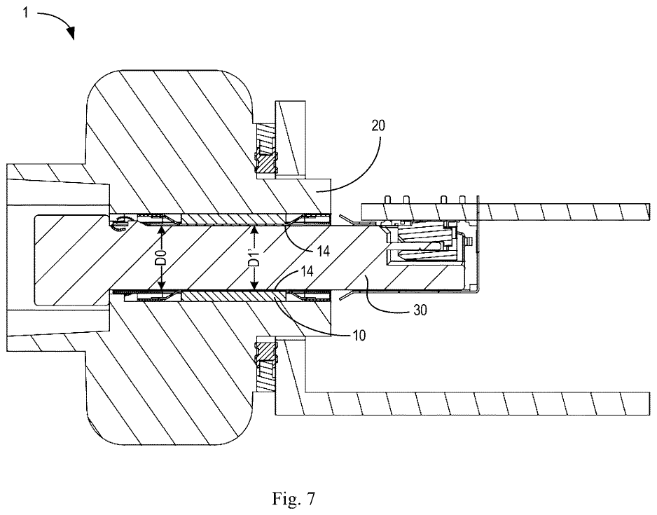

FIG. 6 illustrates an exemplary sectional view of the heatsink system 1 with the transceiver 30 not being coupled to the heatsink system 1, and FIG. 7 illustrates an exemplary sectional view of the heatsink system 1 with the transceiver 30 being coupled to the heatsink system 1.

As shown in FIG. 6, when the transceiver 30 is not inserted into the internal channel 13, a distance DI between the two heat spreaders 14 is smaller than a distance D2 between the first face 125 and the second face 126. The dimension of the transceiver 30 should meet the industrial requirement and/or telecommunication standards, for example, the INF-8074i specification for SFP (Small Form-factor Pluggable) transceiver. Accordingly, the distance D2 between the first face 125 and the second face 126 should meet the industrial requirement and/or telecommunication standards as well to match the transceiver 30. Since the distance D1 between the two heat spreaders 14 is smaller than a distance D2 between the first face 125 and the second face 126, the inserted transceiver 30 can push the heat spreaders 14 to move away from the center of the internal channel 13.

As shown in FIG. 7, when the transceiver 30 is inserted into the internal channel 13, the distance D1′ between the two heat spreaders 14 is larger than D1. The distance Dl′ is equal to a first dimension D0 of the transceiver 30. In this way, the resilient heat conducting material 18 can be compressed. The more the resilient heat conducting material 18 is compressed, the resilient force can be generated by it, which causes better contact between the transceiver 30 and the heatsink 20. Moreover, since the heat spreader 14 also has the ability to be deformed the contact between the transceiver 30 and the heat spreader 14 can be kept stably in any section. The transceiver 30 can be firmly coupled to the heatsink 20 to avoid falling from it. In addition, by the above settings, the heat spreader 14 will not affect the normal operation of the interface module 10 and the transceiver 30, to ensure the normal operation of the interface module 10.

In other example embodiments, the heat spreader 14 and the resilient heat conducting material 18 may be integrally formed as one piece.

In some example embodiments, the resilient heating conducting material 18 may be made of any of the following: gel, grease or phase change material. In this manner, the resilient heating conducting material 18 can conduct the heat from the heat spreader 14 to the heatsink 20 with small thickness.

In other example embodiments, the resilient heating conducting material 18 may be made of a pad. In this manner, the resilient heating conducting material 18 can absorb more assembly tolerance.

In further example embodiments, the resilient heat conducting material 18 may be made of graphite over foam, also referred to as GOF. The graphite over foam can achieve excellent heat dissipation performance due to its high thermal conductivity and good performance stability at high temperature. Moreover, the graphite over foam also has high resilience, which means that when the transceiver 30 is inserted into the internal channel 13, the heat spreader 14 may withstand an adequate resilient force exerted by the resilient heat conducting material 18, and such a force will be transferred to the transceiver 30 via the heat spreader 14. In this way, a firm and stable connection between the transceiver 30 and heat spreader 14 of the interface module 10 can be ensured.

It is to be understood that, apart from the above mentioned materials, the resilient heat conducting material 18 may be made of other materials, depending on the cost consideration of the heatsink system 1, or individual requirement from the user. Here are just a few examples, and the specific materials are not limited to embodiments of the present disclosure.

In the illustrated embodiment, the heatsink 20 further includes two position limits, one of them is configured to couple to the first stop 124 to restrict the movement of the frame 12 along the inserting direction Li; and the other of them is configured to couple to the second stop 123 to restrict the movement of the frame 12 opposite to the inserting direction Li. Moreover, with the help of the first stop 124 and the second stop 123 provided on the interface module 10 and the associated position limit provided on the heatsink 20, the interface module may be fixed to the heatsink without screws and the interface module 10 can self-adjust its posture with relative to the heatsink 20.

It is to be understood that the position limit may be provided as protrusions provided on the heatsink 20, while the first stop 124 and the second stop 123 are provided as recesses provided at the frame 12.

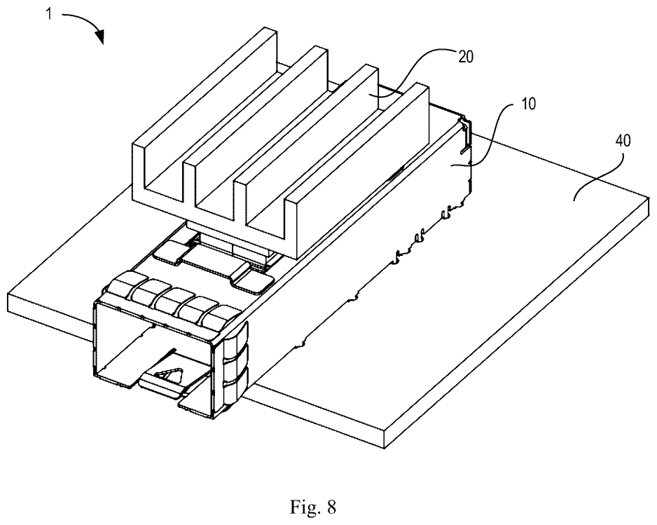

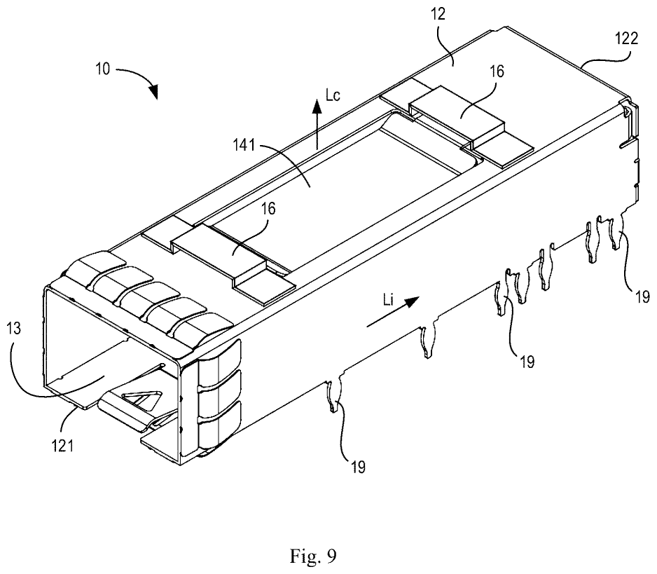

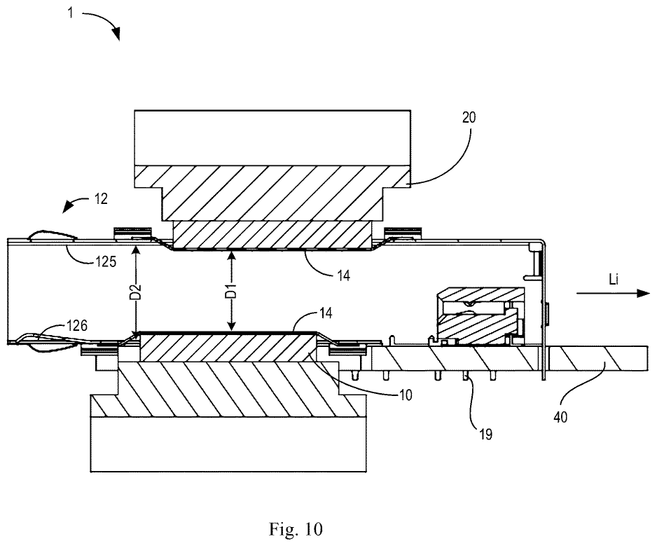

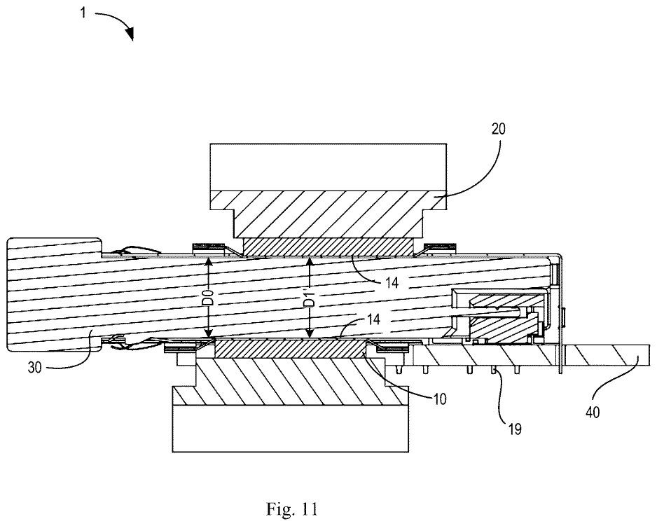

The embodiments described above can be used in a so-call “short cage” known in the art. Another embodiment will be described in more detail hereinafter with reference to FIGS. 8-11, wherein FIG. 8 illustrates an exemplary perspective view of a heatsink system in accordance with other example embodiments of the present disclosure; FIG. 9 illustrates an exemplary perspective view of an interface module in accordance with other example embodiments of the present disclosure; FIG. 10 illustrates an exemplary sectional view of a heatsink system in accordance with other example embodiments of the present disclosure with a transceiver not being coupled to the heatsink system; and FIG. 11 illustrates an exemplary sectional view of a heatsink system in accordance with other example embodiments of the present disclosure with a transceiver being coupled to the heatsink system. The embodiments shown in FIGS. 8-11 differ from those in FIGS. 1-7 in that the former is used in a so-call “long cage” known in the art. The “long cage” can meet the industrial requirement and/or telecommunication standards, for example, the INF-8074i specification.

It is to be understood that in the example embodiment shown in FIG. 8, heat spreader is applied in one side of the frame and in the example embodiments shown in FIGS. 10-11, heat spreader is applied in two sides of the frame.

In the long cage scenario, there is no need to provide the first stop 124 and/or the second stop 123 to connect the interface module 10 and the heatsink 20. In the example embodiments shown in FIGS. 9-11, the interface module 10 may further include one or more teeth 19 to couple to a printed circuit board (PCB) 40.

It is clear that the above solutions described above with reference to the “short cage” scenario can be incorporated into the “long cage” scenario and the details thereof will be omitted for brevity.

As shown in FIG. 10, when the transceiver 30 is not inserted into the internal channel 13, a distance D1 between the two heat spreaders 14 is smaller than a distance D2 between the first face 125 and the second face 126 of the frame 12 of the interface module 10. In this way, the heat spreaders 14 can be pushed away from the center of the internal channel 13 by the inserted transceiver 30.

As shown in FIG. 11, when the transceiver 30 is inserted into the internal channel 13, the distance DI′ between the two heat spreaders 14 is equal to a first dimension D0 of the transceiver 30. In this way, the transceiver 30 can be firmly connected to the heat spreaders 14 to ensure good thermal coupling.

The present disclosure may be adapted to a various scenarios, including the short cage scenario and the long cage scenario. It is to be understood that these are only examples, and the present disclosure may be adapted to other scenarios.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

1. An interface module, comprising:
a frame enclosing an internal channel for receiving at least a heating portion of a heating apparatus in an inserting direction;
at least one heat spreader provided adjacent to an inner wall of the internal channel and configured to contact the heating portion when the heating apparatus is within the internal channel; and
at least one pair of holders attached to the frame and connected to the at least one heat spreader, the holder being configured to restrict a movement of the at least one heat spreader along one or more directions perpendicular to the inserting direction.

2. The interface module of claim 1, wherein the frame comprises a first end, and wherein the frame further comprises a first stop provided adjacent to the first end and configured to restrict a movement of the frame along the inserting direction.

3. The interface module of claim 2, wherein the frame further comprises a second end opposite to the first end, and wherein the frame further comprises a second stop provided adjacent to the second end and configured to restrict the movement of the frame opposite to the inserting direction.

4. The interface module of claim 3, wherein at least one of the first stop or the second stop is formed as a part of the holder.

5. The interface module of claim 1, wherein the at least one heat spreader comprises at least one pair of heat spreader segments which are provided in opposite directions about a central line of the internal channel.

6. The interface module of claim 1, wherein a cross section of the internal channel is of a shape selected from any of the following: rectangle, square, circle, or ellipse.

7. The interface module of claim 1, wherein a cross section of the internal channel is of a rectangle, and the frame comprises:
a first face and a second face opposite to each other;
a third face adjoining the first face and the second face; and
a fourth face adjoining the first face and the second face, the fourth face being opposite to the third face.

8. The interface module of claim 7, wherein the at least one heat spreader further comprises:
a first heat spreader provided at the first face; and
a second heat spreader provided at the second face.

9. The interface module of claim 1, wherein the at least one heat spreader comprises:
a flat surface parallel to the inserting direction and configured to contact the heating portion when the heating apparatus is being inserted; and
at least one tab adjacent to the flat surface and coupled to the holder, so as to restrict the movement of the at least one heat spreader.

10. The interface module of claim 1, wherein the heating apparatus is a small form-factor pluggable transceiver.

11. A heatsink system, comprising:
an interface module of claim 1;
a heatsink coupled to the interface module, wherein a portion of the heatsink is provided outside at least a portion of the interface module; and
at least one resilient heat conducting material provided between the interface module and the portion of the heatsink, wherein the heat generated with the heating apparatus is conducted to the resilient heat conducting material with the at least one heat spreader of the interface module, and then dissipated with the heatsink.

12. The heatsink system of claim 11, wherein the at least one heat spreader is configured to move away from a center of the frame of the interface module when the heating apparatus is inserted into the internal channel of the interface module, so as to compress the resilient heat conducting material along a compressing direction perpendicular to the inserting direction.

13. The heatsink system of claim 11, wherein a cross section of the internal channel of the interface module is of a rectangle, and the frame comprises:
a first face and a second face opposite to each other;
a third face adjoining the first face and the second face; and
a fourth face adjoining the first face and the second face, the fourth face being opposite to the third face, and
wherein the at least one heat spreader of the interface module further comprises:
a first heat spreader provided at the first face; and
a second heat spreader provided at the second face, wherein a distance between the first heat spreader and the second heat spreader when the heating apparatus not being inserted into the internal channel is smaller than a distance between the first face and the second face.

14. The heatsink system of claim 13, wherein a distance between the first heat spreader and the second heat spreader when the heating apparatus is being inserted into the internal channel is equal to a first dimension of the heating apparatus.

15. The heatsink system of claim 11, wherein the at least one heat spreader and the resilient heat conducting material are integrally formed as one piece.

16. The heatsink system of claim 11, wherein the resilient heat conducting material is made of a thermal interface material selected from any of the following: graphite over foam, gel, grease, pad, or phase change material.

17. The heatsink system of claim 11, wherein the frame of the interface module further comprises a first stop and a second stop, and
wherein the heatsink comprises:
a first position limit configured to couple to the first stop to restrict the movement of the frame along the inserting direction; and
a second position limit configured to couple to the second stop to restrict the movement of the frame opposite to the inserting direction.

18. The heatsink system of Claim 11, wherein the first position limit and the second position limit are recesses or protrusions provided on the heatsink, and the first stop and the second stop are protrusions or recesses provided at the frame.
